(19) United States
(12) Patent Application Publication
(10) Pub. No.: US 2004/0109294 A1
(43) Pub. Date: Jun. 10, 2004

(54) Electrical device having antenna assembly

(76) Inventors: Hsien-Chu Lin, Tu-Chen (TW); Chieh Chao Yu, Tu-Chen (TW); Yung-Chien Chung, Tu-Chen (TW)

Correspondence Address: WEI TE CHUNG, FOXCONN INTERNATIONAL, INC., 1650 MEMOREX DRIVE, SANTA CLARA, CA, 95050, US

(21) Appl. No.: 10/329,185

(22) Filed: Dec. 23, 2002

(30) Foreign Application Priority Data
Dec. 10, 2002 (TW) 91135755

(51) Int. Cl. H05K 1/14

(52) U.S. Cl. 361/737

(57) ABSTRACT

A laptop computer (1) removably receives a plug-in combination unit (2). The plug-in combination unit includes a drawer (20), an extension device (4) such as a CD-ROM or disk drive, and an antenna assembly (3). The drawer includes a receiving space (21) for accommodating the extension device. A remainder space (22) is left in the drawer after the drawer accommodates the extension device. The antenna assembly includes an antenna element (31) received in the remainder space of the drawer.

### CROSS-REFERENCE TO RELATED APPLICATION

This application is related to a U.S. patent application entitled “ANTENNA ASSEMBLY AND METHOD OF ASSEMBLING THE SAME” invented by the same inventors, and a U.S. patent application entitled “PANEL ANTENNA AND METHOD FOR INSTALLING THE SAME”, invented by the same inventors, contemporaneously filed and assigned to the same assignee of the present invention.

### BACKGROUND OF THE INVENTION

1. Field of the Invention

The present invention relates to an electrical device, and in particular to an electrical device which accommodates an antenna element therein.

2. Description of the Prior Art

With current developments in communication technology, such as Wireless Local Area Network (WLAN), Bluetooth and HomeRF, many laptop computers now have the function of wireless telecommunication at close range. To achieve this function, an antenna is used with a laptop computer for receiving and transmitting signals. A laptop computer includes a display, a host and a hinge. The hinge interconnects the display and the host so that the display can pivot between an open position and a closed position on the host. One conventional antenna, such as a long-thin-½-wavelength-dipole antenna, is concealed in a top edge of the display. However, as the display goes from the open position to the closed position, the polarity of the pattern moves by 90 degrees. The disadvantage of the location is that as displays get thinner and bigger, such a location is mechanically challenging. A second conventional antenna, such as a rod antenna, projects from a side of the host. However, the antenna is exposed to an outside of the host and can be easily damaged, so the performance of the antenna is not really reliable. A third conventional antenna is assembled into a card, such as a PCMCIA card. The antenna-card assembly is inserted in the laptop computer allowing wireless communications and data transmission. However, because of its integrated structure, this antenna cannot be disassembled from the card. When this antenna or the card is unworkable, the entire antenna-card assembly has to be replaced by a new one. This replacement of the antenna-card assembly is expensive.

Hence, an improved electrical device is desired to overcome the above-mentioned shortcomings of existing antennas.

### BRIEF SUMMARY OF THE INVENTION

An object of the present invention is to provide an electrical device which is capable of protecting an antenna element from damage by the environment.

Another object of the present invention is to provide an electrical device which allows convenient assembly or removal of a component of an antenna assembly to or from the electrical device.

An electrical device in accordance with the present invention comprises a host having a plug-in electrical unit removably received therein. The plug-in electrical unit comprises a drawer, an antenna assembly and an extension device. The drawer comprises a receiving space for accommodating the extension device. A remainder space is left in the drawer after the drawer accommodates the extension device. The antenna assembly comprises an antenna element. The antenna element is received in the remainder space of the drawer.

The electrical device makes full use of the remainder space of the drawer to accommodate the antenna element therein, thereby protecting the antenna element from damage by the environment. Furthermore, replacing the antenna element is convenient.

Other objects, advantages and novel features of the invention will become more apparent from the following detailed description of a preferred embodiment when taken in conjunction with the accompanying drawings.

### BRIEF DESCRIPTION OF THE DRAWINGS

FIG. 1 is a partially disassembled view of an electrical device in accordance with the present invention;

FIG. 2 is a top view of a plug-in combination unit of the electrical device of FIG. 1.

### DETAILED DESCRIPTION OF THE INVENTION

Reference will now be made in detail to a preferred embodiment of the present invention.

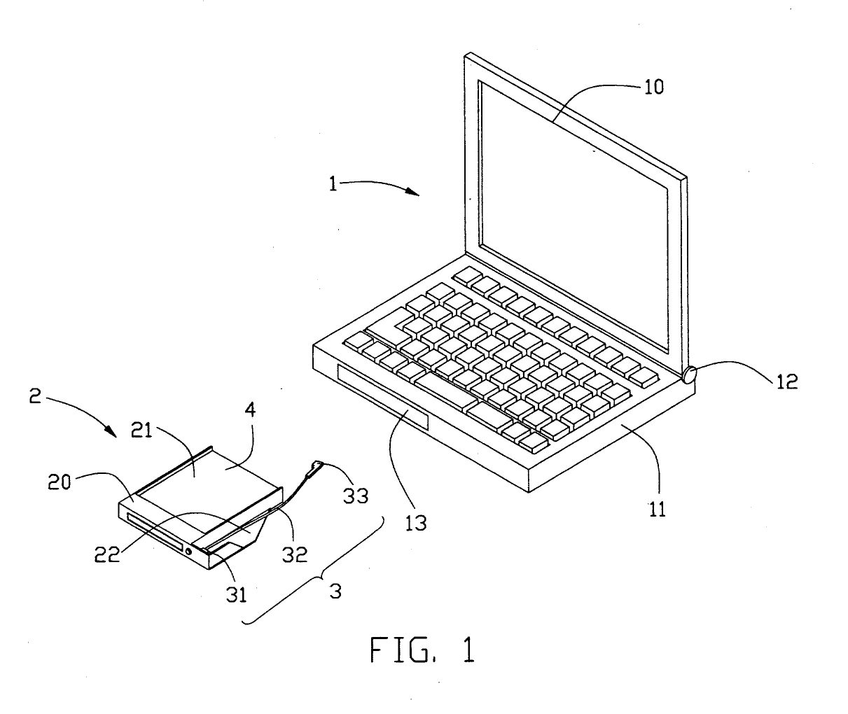

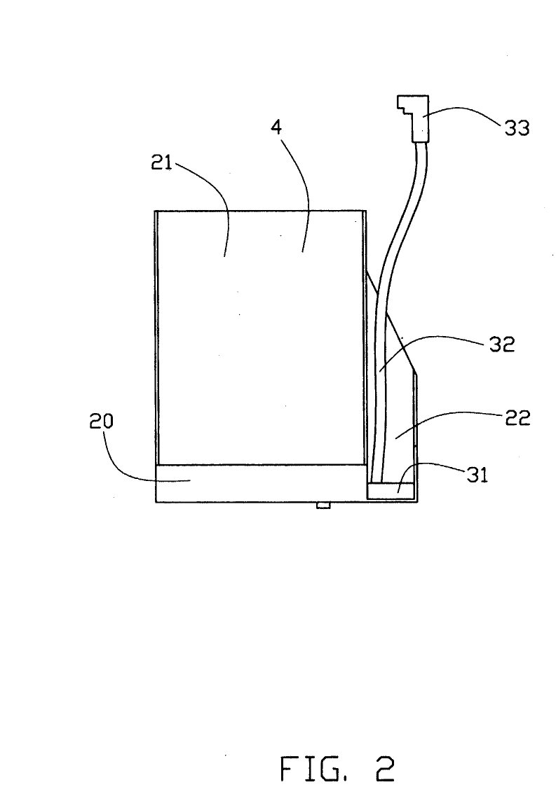

Referring to FIGS. 1 and 2, an electrical device in accordance with a preferred embodiment of the present invention is a laptop computer 1. The laptop computer 1 includes a display 10, a host 11 and a plug-in combination unit 2. The display 10 is pivotally connected to the host 11 through a hinge 12. The host 11 defines a receiving cavity 13 through a front side thereof for receiving the plug-in combination unit 2 therein.

The plug-in combination unit 2 includes a drawer 20, an extension device 4 and an antenna assembly 3. The drawer 20 defines a receiving space 21 for receiving the extension device 4 and a remainder space 22 for receiving the antenna assembly 3. The extension device 4 can be a CD-ROM drive, a floppy disk drive, or a hard disk drive, or another device. Because these extension devices 4 differ in dimensions, the drawer 20 is larger than each kind of extension device 4, thereby accommodating the different kinds of extension devices 4 in accordance with different requirements. The remainder space 22 is left in the drawer 20 after the drawer 20 accommodates a given extension device 4.

The antenna assembly 3 includes an antenna element 31, a coaxial connector 33, and a coaxial feeder cable 32 electrically interconnecting the antenna element 31 and the RF connector 33.

In assembly, the antenna element 31 is mounted in the remainder space 22 in the drawer 20 by a known process such as soldering, screwing, gluing, or other means. The coaxial connector 33 is then securely retained on a rear portion of the drawer 20. The drawer 20 is inserted into the receiving cavity 13 of the laptop computer 1. When the drawer 20 is fully inserted into the receiving cavity 13, the coaxial connector 33 reaches and electrically connects with a complementary connector (not shown) in the laptop computer 1.

In this preferred embodiment, the coaxial connector 33 is fixed on a rear portion of the drawer 20, and automatically mates with the complementary connector without requiring additional manipulation or connection before the drawer 20 is fully inserted into its installed position.

In the electrical device of the present invention, the antenna element 31 is well protected from damage from the environment. Furthermore, either the antenna assembly or the extension device 4 can be easily changed if one or the other develop problem; the entire plug-in combination unit 2 need not be changed, as in the prior art.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical device comprising:
a host defining a receiving cavity; and
a plug-in electrical unit being removably received in the receiving cavity of the host, and comprising a drawer and an antenna assembly, the drawer defining a remainder space, the antenna assembly comprising an antenna element being received in the remainder space.

2. The electrical device as claimed in claim 1, wherein the plug-in electrical unit further comprises an extension device accommodated by the drawer, the remainder space being left in the drawer after the drawer accommodates the extension device.

3. The electrical device as claimed in claim 2, wherein the extension device is a CD-ROM, a floppy disk drive or a hard disk drive.

4. The electrical device as claimed in claim 1, wherein the host is a body portion of a laptop computer.

5. The electrical device as claimed in claim 1, wherein the antenna assembly further comprises an electrical connector, and a feeder cable electrically interconnecting the antenna element and the electrical connector.

6. The electrical device as claimed in claim 5, wherein the electrical connector is a coaxial connector and is securely mounted on the drawer.

7. A method of assembling an antenna in an electrical device, comprising:
providing an antenna assembly comprising an antenna element;
providing an extension device and a drawer, the drawer comprising a receiving space for accommodating the extension device, a remainder space being left in the drawer after the drawer accommodates the extension device;
mounting the antenna element in the remainder space; and
inserting the drawer into the electrical device.

8. The method as claimed in claim 7, wherein the electrical device defines a receiving cavity for removably receiving the drawer.

9. The method as claimed in claim 8, wherein the electrical device is a laptop computer.

10. The method as claimed in claim 9, wherein the extension device is a CD-ROM, a floppy disk drive or a hard disk drive.

11. The method as claimed in claim 7, wherein the antenna assembly further comprises an electrical connector, and a feeder cable interconnecting the antenna element and the electrical connector.

12. The method as claimed in claim 11, wherein the electrical connector is a coaxial connector and is securely mounted on a rear portion of the drawer.

13. An electronic assembly comprising:
a host defining a receiving cavity defining an opening in communication with an exterior;
a metallic drawer compliantly and removably received in said cavity, said drawer defining a primary space receiving a drive therein, and a secondary space, beside said primary space, receiving an antenna assembly therein.

14. The assembly as claimed in claim 13, wherein said primary space and said secondary space are juxtaposed with each other along a lengthwise direction of said host 15. The assembly as claimed in claim 13, wherein said antenna assembly includes an antenna element located adjacent to the opening, and a connector located away from said opening and connected to said antenna element via a wire.
